(19) United States
(12) Patent Application Publication
(10) Pub. No.: US 2026/0147224 A1
(43) Pub. Date: May 28, 2026

(54) Stereoscopic Image Display Device

(71) Applicant: LG Display Co., Ltd., Seoul (KR)

(72) Inventors: Jungeun Lee, Paju-si (KR); HwanKeon Lee, Paju-si (KR); Jeongbeom Lee, Paju-si (KR); Junhyeok Lee, Paju-si (KR)

(21) Appl. No.: 19/220,993

(22) Filed: May 28, 2025

(30) Foreign Application Priority Data
Nov. 27, 2024 (KR) 10-2024-0172061

(51) Int. Cl. G02B 30/27; H10H 29/85; H10H 29/855; H10K 59/38

(52) U.S. Cl. CPC G02B 30/27; H10H 29/8517; H10H 29/8552; H10K 59/38

(57) ABSTRACT

A stereoscopic image display device is disclosed that includes a structure where a display panel including a display area and a non-display area surrounding the display area, and displaying an image through the display area, a 3D lens disposed on one side of the display panel, the display panel including a base substrate, at least one light emitting element disposed on the base substrate, a black matrix disposed over the at least one light emitting element and having at least one first opening, at least one lens disposed in the at least one first opening, and at least one color filter disposed to face the at least one lens, and respective side portions of the at least one lens and the at least one color filter are disposed to correspond to the black matrix in the first opening, and is capable of being lighter and thinner.

### CROSS REFERENCE TO RELATED APPLICATION

This application claims priority from Republic of Korea Patent Application No. 10-2024-0172061, filed on Nov. 27, 2024, which is hereby incorporated by reference in its entirety.

### TECHNICAL FIELD

The present disclosure relates to electronic devices, and more specifically, to stereoscopic image display devices.

### BACKGROUND

Recently, as demands for realistic and immersive images has increased, stereoscopic image display devices configured to display three-dimensional (3D) images have been developed to present the perception of 3D depth to viewers.

Display devices capable of displaying two-dimensional (2D) images have been advanced increasingly and rapidly in terms of image display quality such as resolution, viewing angle, and the like. However, these display devices have a limitation, for example, they cannot present depth information of an image. In contrast, stereoscopic image display devices capable of providing 3D images can present to users with more realistic images when compared to the display devices capable of displaying 2D images.

Left and right screens in an image from stereoscopic image display devices can be presented to left and right eyes of a viewer, respectively. Then, through superimposition and reproduction for the perceived screens by the brain of the viewer, the image can be configured as a single 3D view in front-back, up-down, left-right, and near-far dimensions.

Such stereoscopic image display devices may include, for example, head-mounted displays (HMD) having various forms such as helmets, glasses, goggles, and the like. As stereoscopic image display devices are provided in a wearable form, design challenge arises for making stereoscopic image display devices lighter and thinner.

### SUMMARY

To address these issues, one or more embodiments of the present disclosure may provide a stereoscopic image display device that includes a structure in which at least one lens for controlling left and right viewing angles is disposed inside of a display panel, and is capable of enabling the stereoscopic image display device to be formed lighter and thinner.

One or more embodiments of the present disclosure may provide a stereoscopic image display device that includes a structure in which at least one color filter is disposed in a display panel, and is capable of being used without a polarizing plate.

One or more embodiments of the present disclosure may provide a stereoscopic image display device that includes a structure in which at least one color filter is disposed in a display panel, but a polarizing plate is not disposed therein, and is capable of enabling the stereoscopic image display device to be formed lighter and thinner at low manufacturing costs.

One or more embodiments of the present disclosure may provide a stereoscopic image display device that includes a color filter capable of transmitting light with red, green, and blue wavelengths, and is capable of reducing the number of masks used in manufacturing color filters and thereby reducing manufacturing time and manufacturing cost.

Aspects, examples, and embodiments provided in the present disclosure are not limited to the foregoing description, and additional aspects, examples, and embodiments provided in the present disclosure will become apparent to those skilled in the art from the following description.

According to one or more example embodiments of the present disclosure, a stereoscopic image display device can be provided that includes a display panel including a display area and a non-display area surrounding the display area, and displaying an image through the display area, a 3D lens disposed on one side of the display panel, the display panel including a base substrate, at least one light emitting element disposed on the base substrate, a black matrix disposed over the at least one light emitting element and having at least one first opening, at least one lens disposed in the at least one first opening, and at least one color filter disposed to face the at least one lens. In one or more aspects, in the first opening, respective side portions of the at least one lens and the at least one color filter may correspond to the black matrix.

According to one or more aspects of the present disclosure, a stereoscopic image display device may be provided that includes a structure in which at least one lens for controlling left and right viewing angles is disposed inside of a display panel and is capable of enabling the stereoscopic image display device to be formed lighter and thinner.

According to one or more aspects of the present disclosure, a stereoscopic image display device may be provided that includes a structure in which at least one color filter is disposed in a display panel and is capable of being used without a polarizing plate.

According to one or more aspects of the present disclosure, a stereoscopic image display device may be provided that includes a structure in which at least one color filter is disposed in a display panel, but a polarizing plate is not disposed therein and is capable of enabling the stereoscopic image display device to be formed lighter and thinner at low manufacturing costs.

According to one or more aspects of the present disclosure, a stereoscopic image display device may be provided that includes a color filter capable of transmitting light with red, green, and blue wavelengths and is capable of reducing the number of masks used in manufacturing color filters and thereby reducing manufacturing time and manufacturing cost.

According to one or more aspects of the present disclosure, a stereoscopic image display device may be provided that includes a color filter capable of transmitting light with red, green, and blue wavelengths, and is capable of simplifying a material for forming color filters and being implemented using the simplified material of a one-type element or structure.

Effects or advantages from aspects, examples, and embodiments described herein are not limited thereto, and additional effects or advantages will become apparent to those skilled in the art from the following description.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. It should be therefore understood that aspects, examples, and embodiments described herein are not limited to the illustrations of the accompanying drawings. In the drawings:

FIG. 1 is a system configuration of an example stereoscopic image display device according to embodiments of the present disclosure;

FIG. 2 is an example cross-sectional view of a display area of the stereoscopic image display device according to embodiments of the present disclosure;

FIG. 3 is an example cross-sectional view of a display panel according to embodiments of the present disclosure;

FIG. 4 is a perspective view of an example 3D lens according to embodiments of the present disclosure;

FIG. 5 is an example plan view of the display panel according to embodiments of the present disclosure;

FIG. 6 is another example plan view of the display panel according to embodiments of the present disclosure; and

FIGS. 7 to 24 are example cross-sectional views of the display area of the stereoscopic image display device according to embodiments of the present disclosure.

### DETAILED DESCRIPTION

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting” “make up of”, and “formed of” used herein are generally intended to allow other components to be added unless the terms are used with the term “only”. An element described in the singular form is intended to include a plurality of elements, and vice versa, unless the context clearly indicates otherwise.

Terms, such as “first”, “second”, “A”, “B”, “(A)”, or “(B)” may be used herein to describe elements of the present invention. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, with reference to the accompanying drawings, various example embodiments of the present disclosure will be described in detail.

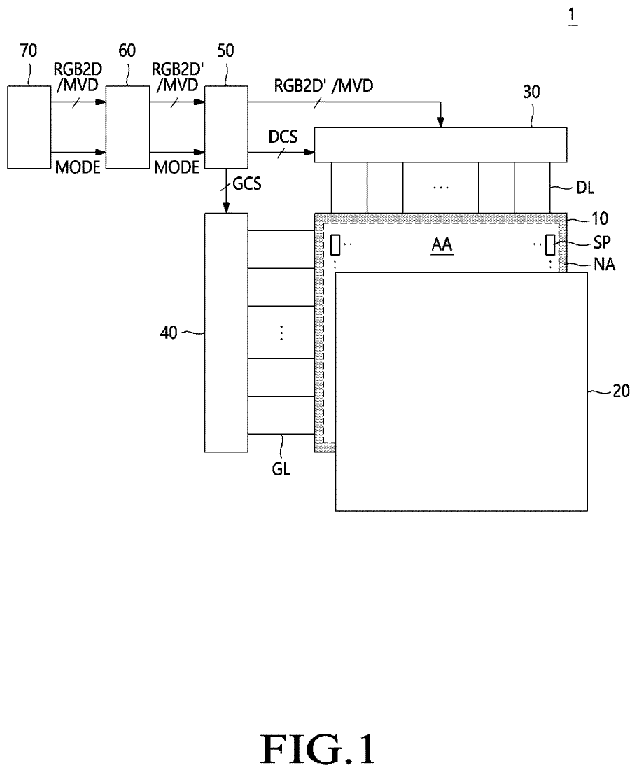

FIG. 1 is a system configuration of an example stereoscopic image display device according to aspects of the present disclosure.

Referring to FIG. 1, in one or more example embodiments, a stereoscopic image display device 1 may include a display panel 10, a 3D lens 20, a data driving circuit 30, a gate driving circuit 40, a timing controller 50, an image processor 60, a host system 70, and the like.

The display panel 10 may include a display area AA in which an image can be displayed and a non-display area NA in which an image is not displayed. The non-display area NA may be an area outside of the display area AA and may also be referred to as a non-active area or a bezel area.

The display panel 10 may include a plurality of subpixels SP. In one or more embodiments, the subpixels SP may be self-emissive light emitting elements such as organic light emitting diodes (OLED), inorganic light emitting diodes (LED), quantum dot (QD) light emitting elements, micro light emitting diodes, mini light emitting diodes, or the like, but aspects of the present disclosure are not limited thereto. The display panel 10 may further include several types of signal lines to drive the plurality of subpixels SP.

The 3D lens 20 can direct each of first to nth (n is a natural number) view images produced through subpixels SP of the display panel 10 onto each of first to nth view areas. For example, the 3D lens 20 can direct a tth (t is a natural number satisfying 1≤t≤n) view image Vt produced through the subpixels SP onto a tth view area VPt.

In one or more aspects, the 3D lens 20 may be a lenticular lens, but aspects of the present disclosure are not limited thereto.

The 3D lens 20 may be disposed in a slanted configuration or a vertical configuration. For example, the slanted configuration may be a structure in which the 3D lens 20 is disposed obliquely at a predetermined angle with respect to subpixels SP of the display panel 10, and the vertical configuration may be a structure in which the 3D lens 20 is disposed parallel to a longitudinal direction (or a vertical direction) of subpixels SP of the display panel 10.

The data driving circuit 30 may include a plurality of source drive integrated circuits (IC). The source drive ICs can convert 2D image data RGB2D′ or multi-view image data MVD into positive and/or negative gamma compensation voltages according to the control of the timing controller 50 and provide positive and/or negative analog data voltages. The data voltages output from the source drive ICs may be supplied to data lines DL of the display panel 10.

The gate driving circuit 40 can sequentially supply gate pulses (or scan pulses) synchronized with data voltages to gate lines GL of the display panel 10 according to the control of the timing controller 50. The gate driving circuit 40 may include a plurality of gate drive integrated circuits each including a shift register, a level shifter configured to convert an output signal from the shift register into a signal with a swing width suitable for driving one or more thin film transistors (TFT) included in the display panel 10, an output buffer, and the like.

The timing controller 50 can receive 2D image data RGB2D′ or multi-view image data MVD, timing signals, a mode signal MODE, and the like from the image processor 60. For example, the timing signals may include a vertical synchronization signal, a horizontal synchronization signal, a data enable signal, a clock signal, and the like.

The timing controller 50 can generate data control signals DCS for controlling the data driving circuit 30 based on the 2D image data RGB2D′ and the timing signals in a 2D mode, and generate gate control signals GCS for controlling the gate driving circuit 40.

The timing controller 50 can generate data control signals DCS for controlling the data driving circuit 30 based on the multi-view image data MVD and the timing signals in a 3D mode and generate gate control signals GCS for controlling the gate driving circuit 40.

The timing controller 50 can supply the gate control signals GCS to the gate driving circuit 40. The timing controller 50 can supply the 2D image data RGB2D′ and the data control signals DCS to the data driving circuit 30 in the 2D mode and supply the multi-view image data MVD and the data control signals DCS to the data driving circuit 30 in the 3D mode.

The host system 70 may be a system-on-chip including a scaler to convert 2D image data RGB2D or multi-view image data MVD input from an external video source device into a data format of a resolution suitable for displaying on the display panel 10.

The host system 70 can supply 2D image data RGB2D or multi-view image data MVD and timing signals to the image processor 60 through an interface such as a low voltage differential signaling (LVDS) interface, a transition minimized differential signaling (TMDS) interface, or the like.

The host system 70 can supply the 2D image data RGB2D and the timing signals to the image processor 60 in the 2D mode and supply the multi-view image data MVD and the timing signals to the image processor 60 in the 3D mode. The host system 70 can supply a mode signal MODE for distinct between the 2D mode and the 3D mode to the image processor 60.

The image processor 60 can distinguish between the 2D mode and the 3D mode based on the mode signal MODE. The image processor 60 can receive the 2D image data RGB2D from the host system 70 in the 2D mode.

The image processor 60 can output 2D image data RGB2D′, which is obtained by converting the 2D image data RGB2D such that all first to nth subpixel (SP) data to be supplied to the first to nth subpixels SP for producing images to be presented in first to nth view areas are reflected into at least one subpixel (SP) data among the first to nth subpixel (SP) data, to the timing controller 50 in the 2D mode.

The image processor 60 can receive the multi-view image data MVD from the host system 70 in the 3D mode. The image processor 60 can output the multi-view image data MVD to the timing controller 50 without converting the multi-view image data MVD in the 3D mode.

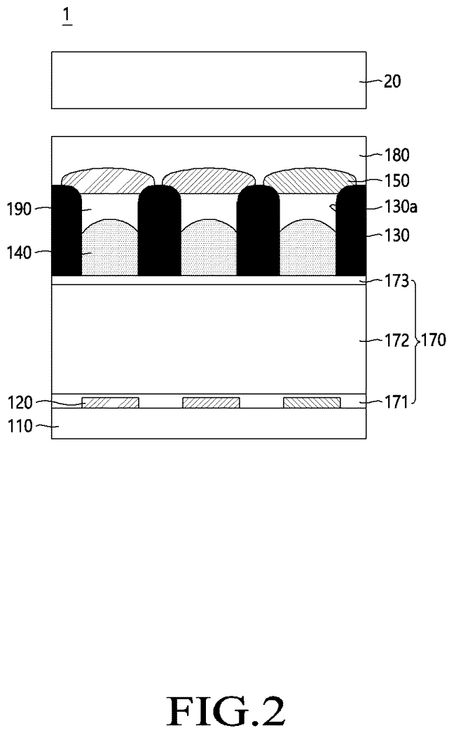

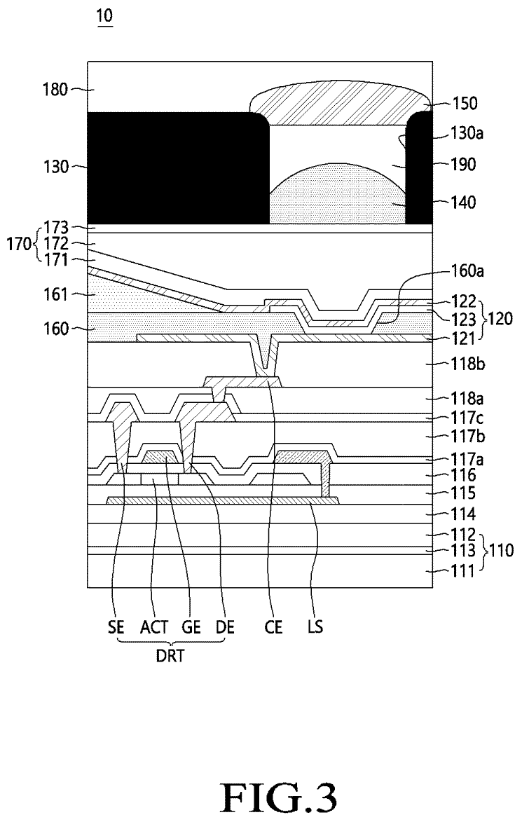

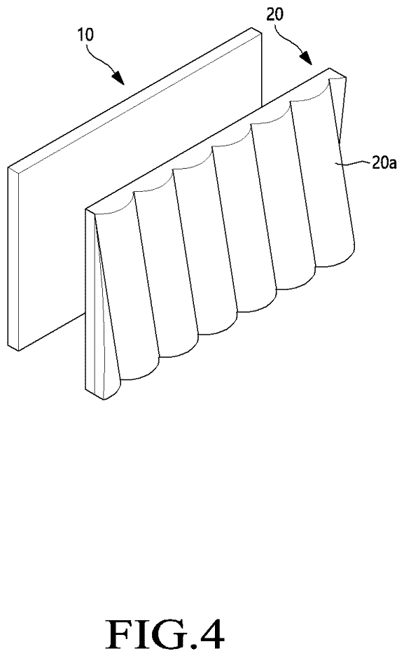

FIG. 2 is an example cross-sectional view of a display area of the stereoscopic image display device 1 according to embodiments of the present disclosure. FIG. 3 is an example cross-sectional view of a display panel 10 according to embodiments of the present disclosure. FIG. 4 is a perspective view of an example 3D lens according to embodiments of the present disclosure.

Referring FIGS. 2 to 4, in one or more example embodiments, the stereoscopic image display device 1 may include a display panel 10 and at least one 3D lens 20.

The display panel 10 may include a display area AA and a non-display area NA surrounding the display area AA and can present images through the display area AA.

The display panel 10 may include a base substrate 110, at least one light emitting element 120, a black matrix 130, at least one lens 140, and at least one color filter 150.

The base substrate 110 may include two or more layers. For example, the base substrate 110 may include a first base substrate 111, a second base substrate 112, and an insulating layer 113 disposed between the first base substrate 111 and the second base substrate 112.

The first base substrate 111 and the second base substrate 112 may include polyimide (PI). Polyimide (PI) may be a polymer with a relatively low crystallinity or mostly amorphous structure, be easily synthesized to form a thin film, and have advantages of good transparency, heat resistance, and mechanical properties. However, since the polyimide (PI) has poor moisture resistance, the moisture resistance of the base substrate 110 may be improved by disposing an insulating layer 113 including an inorganic insulating material such as silicon nitride (SiNx), silicon oxide (SiOx), and the like between the first base substrate 111 and the second base substrate 112.

At least one buffer layer may be disposed on the second base substrate 112 to block moisture and oxygen coming from the outside. For example, the at least one buffer layer may include a multi-buffer layer 114 and an active buffer layer 115.

The multi-buffer layer 114 may serve to block moisture and oxygen passing through the base substrate 110. For example, the multi-buffer layer 114 may include an inorganic material such as silicon nitride (SiNx), silicon oxide (SiOx), silicon oxynitride (SiON), aluminum oxide (Al2O3), and/or the like.

A light shielding layer LS may be disposed between the multi-buffer layer 114 and the active buffer layer 115 to prevent light coming from the outside from reaching a drive transistor DRT. For example, the active buffer layer 115 may be disposed on the multi-buffer layer 114 such that the active buffer layer 115 covers the light shielding layer LS. The active buffer layer 115 may include, for example, an inorganic material such as silicon nitride (SiNx), silicon oxide (SiOx), silicon oxynitride (SiON), aluminum oxide (Al2O3), and/or the like.

The drive transistor DRT may be disposed on the active buffer layer 115. The drive transistor DRT can drive a light emitting element 120 by controlling current flowing through the light emitting element 120. For example, the drive transistor DRT may be electrically connected to a first electrode 121, which is described later.

The drive transistor DRT may include an active layer ACT, a gate electrode GE, a source electrode SE, and a drain electrode DE.

At least one inorganic layer may be disposed on the active buffer layer 115 to form one or more elements related to the drive transistor DRT. For example, the at least one inorganic layer may include a gate insulating layer 116, a first interlayer insulating layer 117a, a second interlayer insulating layer 117b, and a third interlayer insulating layer 117c.

The gate insulating layer 116 may be disposed on the active buffer layer 115 such that the gate insulating layer 116 covers the active layer ACT.

The gate electrode GE may be disposed on the gate insulating layer 116. Further, the first interlayer insulating layer 117a may be disposed on the gate insulating layer 116 such that the first interlayer insulating layer 117a covers the gate electrode GE.

The second interlayer insulation layer 117b may be disposed on the first interlayer insulation layer 117a. Further, the source electrode SE and the drain electrode DE may be disposed on the second interlayer insulating layer 117b. The source electrode SE and the drain electrode DE may be connected to respective portions of the active layer ACT, which forms a channel when the drive transistor DRT is driven, though contact holes of the gate insulating layer 116, the first interlayer insulating layer 117a, and the second interlayer insulating layer 117b.

The source electrode SE and the drain electrode DE may be covered by the third interlayer insulating layer 117c.

A first interlayer planarization layer 118a may be disposed on the third interlayer insulating layer 117c to provide a flat surface over the source electrode SE and the drain electrode DE in the configuration where the source electrode SE and the drain electrode DE is covered by the third interlayer insulating layer 117c.

A connection electrode CE may be disposed on the first interlayer planarization layer 118a. The connection electrode CE may electrically connect a first electrode 121 to the drain electrode DE through contact holes of the third interlayer insulating layer 117c and the first interlayer planarization layer 118a.

A second interlayer planarization layer 118b may be disposed on the first interlayer planarization layer such that the second interlayer planarization layer 118b covers the connection electrode CE. In this configuration, the first electrode 121 may be connected to the connection electrode CE through a contact hole formed in the second interlayer planarization layer 118b.

At least one light emitting element 120 may be disposed over the base substrate 110. For example, the at least one light emitting element 120 may be disposed on the second interlayer planarization layer 118b. In one or more embodiments, the at least one light emitting element 120 may be an organic light emitting element including a first electrode 121, which may be a pixel electrode (or an anode electrode), a second electrode 122, which may be a common electrode (or a cathode electrode), and an emission layer 123 interposed between the first electrode 121 and the second electrode 122.

A black matrix 130, which may be formed in a single layer, may be disposed on the at least one light emitting element 120. For example, the black matrix 130 may include at least one opening including a first opening 130a. For example, the first opening 130a may be disposed in a light emitting area overlapping with the emission layer 123.

In one or more embodiments, at least one lens 140 may be disposed for collecting light emitted from the at least one light emitting element 120 to place the stereoscopic image display device 1 at a narrow viewing angle. For example, the at least one lens 140 may be a convex lens formed convexly in a location facing at least one color filter 150. However, shapes of the lens 140 according to embodiments of the present disclosure are not limited thereto, and the at least one lens 140 may be a concave lens formed concavely in a location facing the at least one color filter 150. For example, the at least one lens 140 may be a convex lens in the stereoscopic image display device 1 having a top-emission structure, or a concave lens in the stereoscopic image display device 1 having a bottom-emission structure.

The lens 140 may be disposed in the first opening 130a. For example, the lens 140 may be disposed such that the lens 140 overlaps with the emission layer 123 and be disposed in the first opening 130a by an inkjet printing process.

In the example where the lens 140 is formed by the inkjet printing process, the lens 140 can be easily manufactured with a desired thickness and shape. Further, since light focused through the at least one lens 140 can be directed toward the at least one color filter 150, the luminance of the stereoscopic image display device 1 can be improved.

The at least one color filter 150 may include red, green, and blue color filters, and may be disposed such that the at least one color filter 150 faces the at least one lens 140. For example, the color filter 150 may be disposed in the first opening 130a of the black matrix 130 and may be disposed such that the color filter 150 faces the lens 140 while being disposed over or under the lens 140. For example, the color filter 150, the lens 140, and the emission layer 123 may be disposed in parallel to each other and overlap with each other. For example, respective parts or all of the lens 140 and the color filter 150 may be disposed in the first opening 130a, and therefore, respective side portions or partial side portions of the lens 140 and the color filter 150 in the first opening 130a may correspond to, or contact, the black matrix 130.

The at least one color filter 150 may have a shape where an upper portion of the at least one color filter 150 is convex or concave. For example, the at least one color filter 150 may be formed by a patterning process using a photomask or an inkjet printing process.

Although the at least one color filter 150 is illustrated and described as including a red color filter, a green color filter, and a blue color filter, however, aspects of the present disclosure are not limited thereto. For example, the at least one color filter 150 may be a one-type color filter formed to allow all of the wavelengths of red, green, and blue to be transmitted. In this example, the number of masks required to manufacture such a one-type color filter 150 can be reduced, and thereby, manufacturing time and manufacturing cost can be reduced.

The 3D lens 20 may be disposed on one side of the display panel 10 and can form a stereoscopic image according to binocular parallax. For example, the 3D lens 20 may have a form in which a plurality of lenticular lenses 20a having a hemispherical cross-section are regularly arranged. According to this example, light emitted from the at least one light emitting element 120 may reach left and right eyes of a user, respectively, by the lenticular lens 20a, and then, the user can perceive a stereoscopic image by stereo graphics.

Although FIG. 4 illustrates that the lenticular lens 20 a included in the 3D lens 20 are disposed in a slanted configuration in which the lenticular lens 20a are disposed obliquely at a predetermined angle from subpixels SP. However, embodiments of the present disclosure are not limited thereto. For example, the lenticular lens 20 a included in the 3D lens 20 may be disposed in a vertical configuration in which the lenticular lens 20a are disposed parallel to the subpixels SP in a vertical direction.

The display panel 10 may further include a bank layer 160, an encapsulation layer 170, a first planarization layer 180, and a second planarization layer 190.

The bank layer 160 may define one or more light emitting areas by separating pixels. Referring to FIG. 3, the bank layer 160 may include a second opening 160a formed in an area corresponding to the first opening 130a. For example, the bank layer 160 may include the second opening 160a for exposing a portion of the first electrode 121 located under the bank layer 160. According to this example, the first electrode 121 may contact the emission layer 123 through the second opening 160a.

The bank layer 160 may include a material including a black pigment, or an organic material such as a benzocyclobutene resin, a polyimide resin, an acrylic resin, a photosensitive polymer, or the like.

In one or more embodiments, when forming the emission layer 123 located on the bank layer 160, a fine metal mask (FMM) as a deposition mask may be used. In this implementation, a spacer 161 may be disposed on the bank layer 160 to prevent damage that may occur due to contact between the bank layer 160 and the deposition mask and to maintain a certain distance between the bank layer 160 and the deposition mask.

The encapsulation layer 170 may be disposed on the light emitting element 120 to cover the light emitting element 120. According to this configuration, the light emitting element 120 can be protected from external moisture, oxygen, impact, and the like through the encapsulation layer 170.

The encapsulation layer 170 may include a first encapsulation layer 171, a second encapsulation layer 172, and a third encapsulation layer 173.

The first encapsulation layer 171 may include an inorganic material capable of being deposited at low temperature, such as silicon nitride (SiNx), silicon oxide (SiOx), silicon oxynitride (SiON), aluminum oxide (Al2O3), or the like, but aspects of the present disclosure are not limited thereto. In the example where the first encapsulation layer 171 is deposited in a low temperature atmosphere, the first encapsulation layer 171 can prevent the emission layer 123 including an organic material vulnerable to a high temperature atmosphere during the deposition process from being damaged.

The second encapsulation layer 172 may be disposed on the first encapsulation layer 171. For example, the second encapsulation layer 172 may include an organic insulating material such as acrylic resin, epoxy resin, polyimide, polyethylene, silicon oxycarbon (SiOC), or the like, but aspects of the present disclosure are not limited thereto. In the example where the second encapsulation layer 172 include an organic material, the second encapsulation layer 172 can encapsulate elements disposed under the second encapsulation layer 172 and alleviate a step difference.

The third encapsulation layer 173 may be disposed on the second encapsulation layer 172. For example, the third encapsulation layer 173 may include an inorganic material such as silicon nitride (SiNx), silicon oxide (SiOx), silicon oxynitride (SiON), aluminum oxide (Al2O3), or the like, but aspects of the present disclosure are not limited thereto.

As discussed above, since the encapsulation layer 170 include a plurality of layers, the encapsulation layer 170 can effectively protect the light emitting element 120 by minimizing the penetration of moisture or oxygen from the outside.

The first planarization layer 180 may be disposed under the 3D lens 20 and cover the at least one lens 140 or the at least one color filter 150. For example, when the at least one color filter 150 is disposed on the at least one lens 140, the first planarization layer 180 may cover the at least one color filter 150, or when the at least one color filter 150 is disposed under the at least one lens 140, the first planarization layer 180 may cover the at least one lens 140.

The first planarization layer 180 may include an organic material such as an acrylic resin, an epoxy resin, a phenolic resin, a polyamide resin, a polyimide resin, or the like. Accordingly, the first planarization layer 180 can alleviate a step difference caused by elements or layers disposed under the first planarization layer 180.

The second planarization layer 190 may be disposed between the at least one lens 140 and the at least one color filter 150. For example, the second planarization layer 190 may cover the at least one lens 140, and the at least one color filter 150 may be disposed on the second planarization layer 190.

The second planarization layer 190 may include an organic material such as an acrylic resin, an epoxy resin, a phenolic resin, a polyamide resin, a polyimide resin, or the like, as in the example of the first planarization layer 180. Accordingly, the second planarization layer 190 can alleviate a step difference caused by elements or layers disposed under the second planarization layer 190.

A protective layer (not shown in the drawings) may be disposed on the second planarization layer 190 to prevent moisture and undesired substances from entering the at least one lens 140.

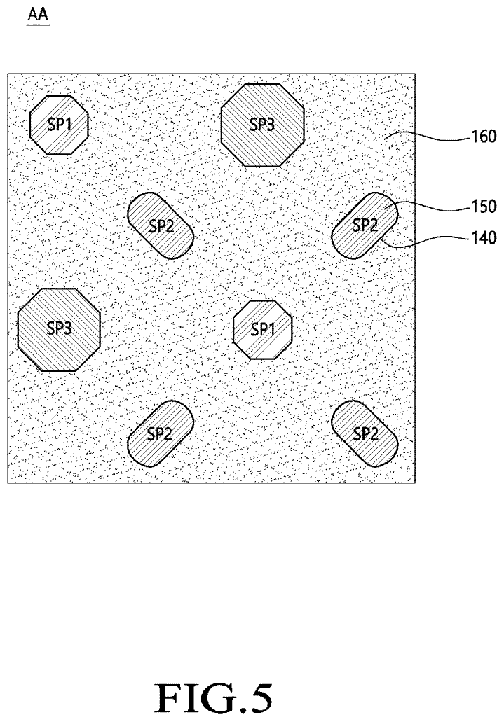

FIG. 5 is an example plan view of the display panel 10 according to embodiments of the present disclosure.

Referring to FIG. 5, the display panel 10 may include at least one first red subpixel SP1, at least one second green subpixel SP2, and at least one third blue subpixel SP3. In one or more aspects, all, or one or more, of the at least one first subpixel SP1, the at least one second subpixel SP2, and the at least one third subpixel SP3 may be formed in an asymmetrical shape.

Each of the subpixels (SP1, SP2, and SP3) may be exposed through a corresponding second opening 160a among openings of the bank layer 160, and a corresponding lens 140 and a corresponding color filter 150 may be disposed to overlap with each of the subpixels (SP1, SP2, and SP3).

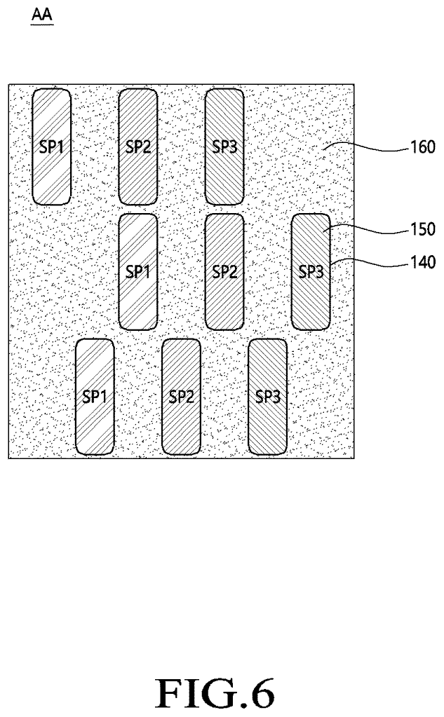

FIG. 6 is another example plan view of the display panel 10 according to embodiments of the present disclosure. Discussions that follow for the configurations of FIG. 6 are provided by focusing on configurations different from the configurations of FIGS. 1 to 5, for simplicity.

Referring to FIG. 6, the display panel 10 may include at least one first red subpixel SP1, at least one second green subpixel SP2, and at least one third blue subpixel SP3. In one or more aspects, all, or one or more, of the at least one first subpixel SP1, the at least one second subpixel SP2, and the at least one third subpixel SP3 may be formed in a symmetrical shape. For example, first subpixels SP1, second subpixels SP2, and third subpixels SP3 may be formed in a rectangular shape and disposed adjacent to each other. The arrangements of the first subpixels SP1, the second subpixels SP2, and the third subpixels SP3 are not limited thereto and may be variously changed.

When the first subpixels SP1, the second subpixels SP2, and the third subpixels SP3 are formed in a rectangular shape, lenses 140 and color filters 150 disposed on these subpixels may be formed more easily by an inkjet printing process.

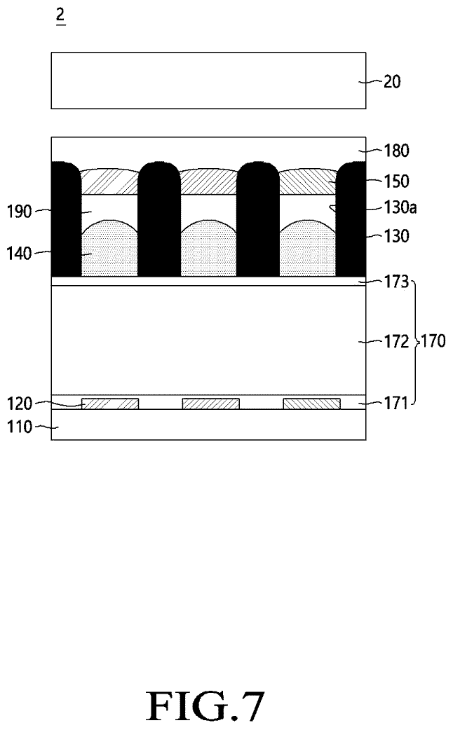

FIG. 7 is a cross-sectional view of a display area DA of a stereoscopic image display device according to another embodiment of the present disclosure. Discussions that follow for the configurations of FIG. 7 are provided by focusing on configurations different from the configurations of FIGS. 1 to 6, for simplicity.

Referring to FIG. 7, a stereoscopic image display device 2 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120.

The base substrate 110 may support various components or layers of the stereoscopic image display device 2 and may include a stack of a plurality of layers.

The light emitting element 120 may be disposed over the base substrate 110, and may include a first electrode 121, which is a pixel electrode (or an anode electrode), a second electrode 122, which is a common electrode (or a cathode electrode), and an emission layer 123 interposed between the first electrode 121 and the second electrode 122.

An encapsulation layer 170 may be disposed on the light emitting element 120 to protect the light emitting element 120 and flatten one or more stacked configurations. For example, the encapsulation layer 170 may include a first encapsulation layer 171 covering the second electrode 122, a second encapsulation layer 172 disposed on the first encapsulation layer 171, and a third encapsulation layer 173 disposed on the second encapsulation layer 172.

The black matrix 130 may be disposed on the encapsulation layer 170, and a first openings 130a may be formed in an area overlapping with the emission layer 123.

The black matrix 130 may be in the form of a single layer. When the black matrix 130 is in the form of a single layer, a thickness of the stereoscopic image display device 2 can be reduced compared to a black matrix in the form of multiple layers.

The lens 140 may be used to collect light emitted from the light emitting element 120 to place the stereoscopic image display device 2 at a narrow viewing angle and may be disposed in the first opening 130a of the black matrix 130. For example, the lens 140 may be a convex lens formed convexly toward the color filter 150. In this example, a curvature of the lens 140 may be proportional to a surface energy difference with an element or layer contacting a curve side of the lens 140. For example, as a surface energy difference between the lens 140 and the black matrix 130 increases, a curvature of the lens 140 may increase, and as a surface energy difference between the lens 140 and the black matrix 130 decreases a curvature of the lens 140 may decrease.

The lens 140 may be disposed in the first opening 130a of the black matrix 130. For example, when the black matrix 130 includes a plurality of first opening 130a, the lens array may also include a plurality of lens 140, and each of the plurality of lens 140 may be disposed in a corresponding one of the plurality of first opening 130a. In one or more aspects, the lens 140 may be disposed to overlap with the emission layer 123 and may be formed in a convex shape in the first opening 130a by an inkjet printing process.

A second planarization layer 190 may be disposed on an uneven upper surface of the lens 140 to provide a flattened surface. For example, the second planarization layer 190 may be disposed in the first opening 130a of the black matrix 130 and cover an upper portion of the lens 140. According to this configuration, since the second planarization layer 190 is disposed on the lens 140, the stereoscopic image display device 2 can provide advantages of planarizing an convex upper surface of the lens 140 and preventing moisture and undesired substances from penetrating toward the lens 140.

For example, the color filter array may include red, green, and blue color filters 150. In this example, each of these color filters may be disposed in a corresponding one of the first openings 130a of the black matrix 130 and cover an upper portion of the second planarization layer 190. For example, the color filter 150 may be formed to have a convex shape in a direction facing the 3D lens 20 by a patterning process using a photomask or an inkjet printing process. In this example, a curvature of the color filter 150 may be proportional to a surface energy difference with an element or layer contacting a curve side of the color filter 150. For example, as a surface energy difference between the color filter 150 and the black matrix 130 increases, a curvature of the color filter 150 may increase, and as a surface energy difference between the color filter 150 and the black matrix 130 decreases, a curvature of the color filter 150 may decrease.

On a same horizontal surface, the sum of respective maximum heights of the lens 140, the second planarization layer 190, and the color filter 150 may be formed smaller than a height of the black matrix 130. For example, the lens 140, the second planarization layer 190, and the color filter 150 may be disposed in the first opening 130a of the black matrix 130 and may not protrude outside of the black matrix 130.

According to this configuration, when the lens 140, the second planarization layer 190, and the color filter 150 are disposed inside of the black matrix 130, a thickness of the display panel 10 can be reduced, and thereby, the stereoscopic image display device 2 can be formed lighter and thinner.

The 3D lens 20 may be disposed on one side of the display panel 10 and can form a stereoscopic image according to binocular parallax. For example, the 3D lens 20 may include a lenticular lens 20a, and a user can perceive a stereoscopic image through the lenticular lens 20a.

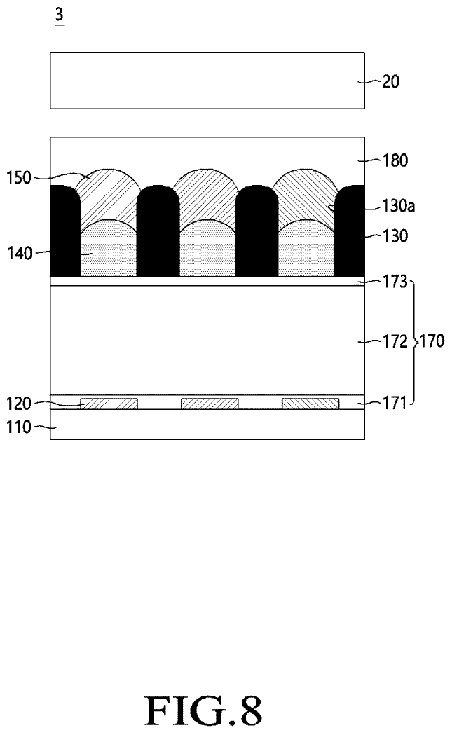

FIG. 8 is a cross-sectional view of a display area DA of a stereoscopic image display device according to another embodiment of the present disclosure. Discussions that follow for the configurations of FIG. 8 are provided by focusing on configurations different from the configurations of FIGS. 1 to 7, for simplicity.

Referring to FIG. 8, a stereoscopic image display device 3 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120. In one or more aspects, the stereoscopic image display device 3 may not include a second planarization layer 190 when compared to the stereoscopic image display device 2 of FIG. 7 described above. In this configuration, since the second planarization layer 190 is omitted from the display panel 10, a thickness of the display panel 10 can be reduced, and thereby, the stereoscopic image display device 3 can be formed lighter and thinner.

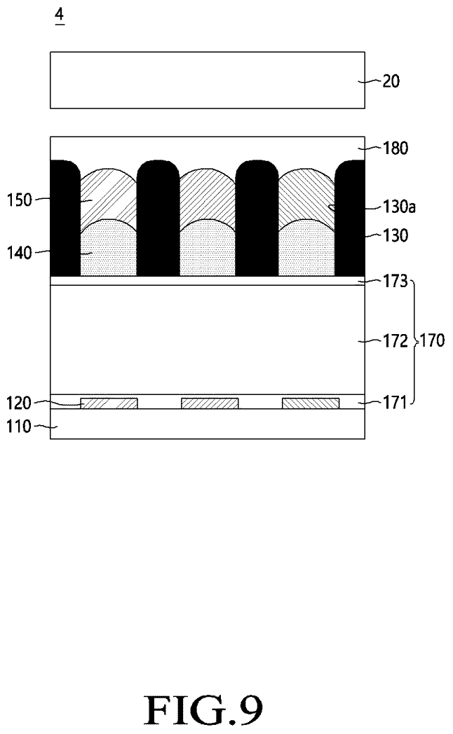

FIG. 9 is a cross-sectional view of a display area DA of a stereoscopic image display device according to another embodiment of the present disclosure. Discussions that follow for the configurations of FIG. 9 are provided by focusing on configurations different from the configurations of FIGS. 1 to 8, for simplicity.

Referring to FIG. 9, a stereoscopic image display device 4 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120.

The stereoscopic image display device 4 may be formed such that on a same horizontal surface, the sum of respective maximum heights of the lens 140 and the color filter 150 is smaller than a height of the black matrix 130 when compared to the stereoscopic image display device 3 of FIG. 8. For example, the lens 140 and the color filter 150 may be disposed in a first opening 130a of the black matrix 130 and may not protrude outside of the black matrix 130.

According to this configuration, when the lens 140 and the color filter 150 are disposed inside of the black matrix 130, a thickness of the display panel 10 can be reduced, and thereby, the stereoscopic image display device 4 can be formed lighter and thinner.

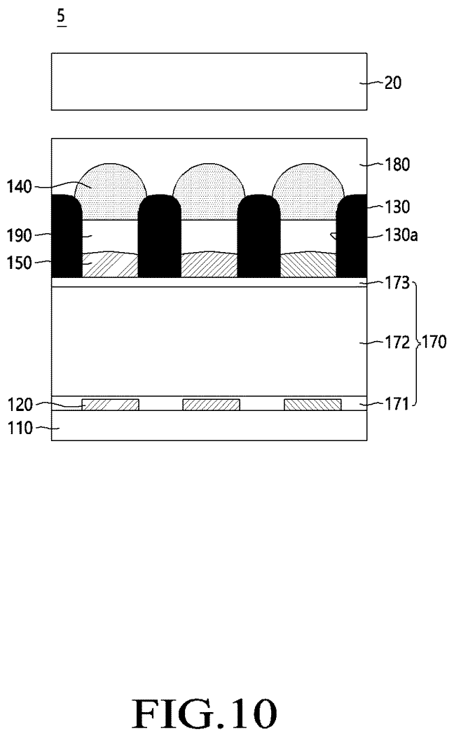

FIG. 10 is a cross-sectional view of a display area DA of a stereoscopic image display device according to another embodiment of the present disclosure. Discussions that follow for the configurations of FIG. 10 are provided by focusing on configurations different from the configurations of FIGS. 1 to 9, for simplicity.

Referring to FIG. 10, a stereoscopic image display device 5 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120.

The base substrate 110 may support various components or layers of the stereoscopic image display device 5 and may include a stack of a plurality of layers.

The light emitting element 120 may be disposed over the base substrate 110, and may include a first electrode 121, which is a pixel electrode (or an anode electrode), a second electrode 122, which is a common electrode (or a cathode electrode), and an emission layer 123 interposed between the first electrode 121 and the second electrode 122.

An encapsulation layer 170 may be disposed on the light emitting element 120 to protect the light emitting element 120 and flatten one or more stacked configurations.

The black matrix 130 may be disposed on the encapsulation layer 170, and a first opening 130a may be formed in an area overlapping with the emission layer 123.

The color filter 150, a second planarization layer 190, and the lens 140 may be sequentially stacked in the first opening 130a of the black matrix 130. For example, when compared to the stereoscopic image display device 2 of FIG. 7, locations of the color filter 150 and the lens 140 of the stereoscopic image display device 5 of FIG. 10 may be interchanged. The locations of the color filter 150 and the lens 140 may be changed as needed depending on related processes.

On a same horizontal surface, the sum of respective maximum heights of the color filter 150 and a second planarization layer 190 may be formed to be less than a height of the black matrix 130. For example, the color filter 150 and the second planarization layer 190 may be disposed in the first opening 130a of the black matrix 130 and may not protrude outside of the black matrix 130.

According to this configuration, when the color filter 150 and the second planarization layer 190 are located inside of the black matrix 130, a thickness of the display panel 10 can be reduced, and thereby, the stereoscopic image display device 5 can be formed lighter and thinner.

The 3D lens 20 may be disposed on one side of the display panel 10 and can form a stereoscopic image according to binocular parallax. For example, the 3D lens 20 may include a lenticular lens 20a, and a user can perceive a stereoscopic image through the lenticular lens 20a.

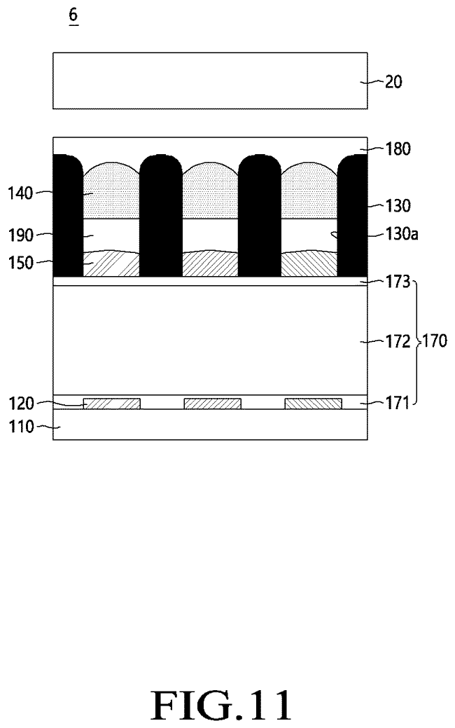

FIG. 11 is a cross-sectional view of a display area DA of a stereoscopic image display device according to another embodiment of the present disclosure. Discussions that follow for the configurations of FIG. 11 are provided by focusing on configurations different from the configurations of FIGS. 1 to 10, for simplicity.

Referring to FIG. 11, a stereoscopic image display device 6 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120.

The stereoscopic image display device 6 may be formed such that on a same horizontal surface, the sum of respective maximum heights of the color filter 150, a second planarization layer 190 and the lens 140 is smaller than a height of the black matrix 130 when compared to the stereoscopic image display device 5 of FIG. 10. For example, the color filter 150, the second planarization layer 190, and the lens 140 may be disposed in a first opening 130a of the black matrix 130 and may not protrude outside of the black matrix 130.

According to this configuration, when the color filter 150, the second planarization layer 190 and the lens 140 are disposed inside of the black matrix 130, a thickness of the display panel 10 can be reduced, and thereby, the stereoscopic image display device 6 can be formed lighter and thinner.

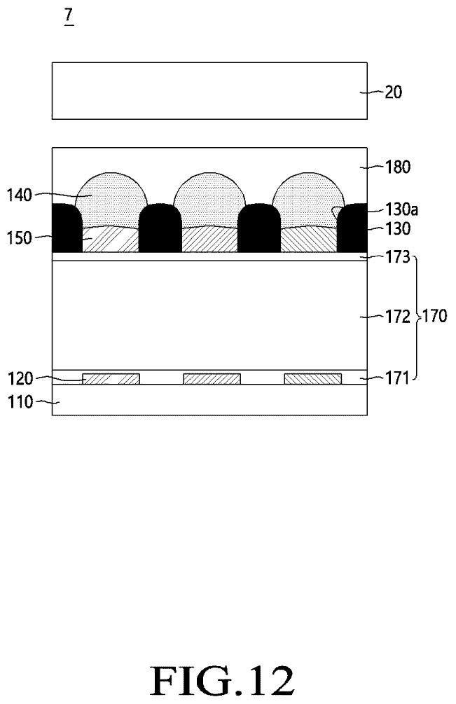

FIG. 12 is a cross-sectional view of a display area DA of a stereoscopic image display device according to another embodiment of the present disclosure. Discussions that follow for the configurations of FIG. 12 are provided by focusing on configurations different from the configurations of FIGS. 1 to 11, for simplicity.

Referring to FIG. 12, a stereoscopic image display device 7 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120. In one or more aspects, the stereoscopic image display device 7 may not include a second planarization layer 190 when compared to the stereoscopic image display device 6 of FIG. 11 described above. In this configuration, since the second planarization layer 190 is omitted from the display panel 10, a thickness of the display panel 10 can be reduced, and thereby, the stereoscopic image display device 7 can be formed lighter and thinner.

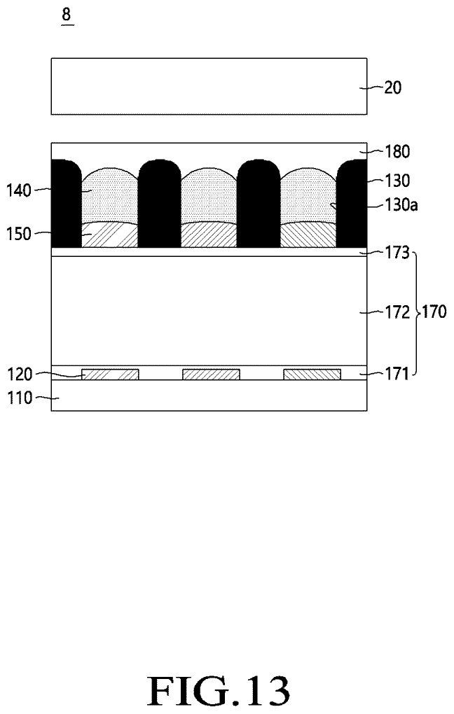

FIG. 13 is a cross-sectional view of a display area DA of a stereoscopic image display device according to another embodiment of the present disclosure. Discussions that follow for the configurations of FIG. 13 are provided by focusing on configurations different from the configurations of FIGS. 1 to 12, for simplicity.

Referring to FIG. 13, a stereoscopic image display device 8 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120.

The stereoscopic image display device 8 may be formed such that on a same horizontal surface, the sum of respective maximum heights of the color filter 150 and the lens 140 is smaller than a height of the black matrix 130 when compared to the stereoscopic image display device 7 of FIG. 12. For example, the color filter 150 and the lens 140 may be disposed in a first opening 130a of the black matrix 130 and may not protrude outside of the black matrix 130.

According to this configuration, when the color filter 150 and the lens 140 are disposed inside of the black matrix 130, a thickness of the display panel 10 can be reduced, and thereby, the stereoscopic image display device 8 can be formed lighter and thinner.

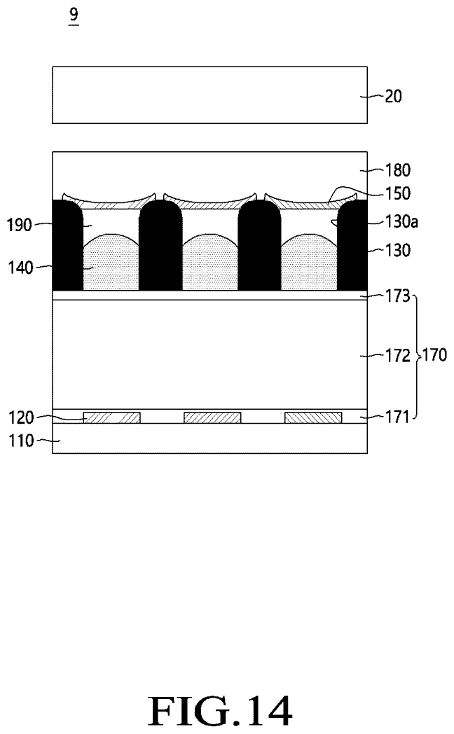

FIG. 14 is a cross-sectional view of a display area DA of a stereoscopic image display device according to another embodiment of the present disclosure. Discussions that follow for the configurations of FIG. 14 are provided by focusing on configurations different from the configurations of FIGS. 1 to 13, for simplicity.

Referring to FIG. 14, a stereoscopic image display device 9 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120.

The base substrate 110 may support various components or layers of the stereoscopic image display device 9 and may include a stack of a plurality of layers.

The light emitting element 120 may be disposed over the base substrate 110, and may include a first electrode 121, which is a pixel electrode (or an anode electrode), a second electrode 122, which is a common electrode (or a cathode electrode), and an emission layer 123 interposed between the first electrode 121 and the second electrode 122.

An encapsulation layer 170 may be disposed on the light emitting element 120 to protect the light emitting element 120 and flatten one or more stacked configurations.

The black matrix 130 may be disposed on the encapsulation layer 170, and a first opening 130a may be formed in an area overlapping with the emission layer 123.

In one or more embodiments, the lens 140 may be disposed for collecting light emitted from the light emitting element 120 to place the stereoscopic image display device 9 at a narrow viewing angle. For example, the lens 140 may be a convex lens formed convexly toward the color filter 150.

The lens array may include a plurality of lens 140, and the black matrix 130 may include a plurality of first openings 130a. In this implementation, each of the plurality of lens 140 may be disposed in a corresponding one of the plurality first openings 130a of the black matrix 130. In one or more embodiments, the lens 140 may be disposed to overlap with the emission layer 123 and may be formed in a convex shape in the first opening 130a by an inkjet printing process.

A second planarization layer 190 may be disposed on an uneven upper surface of the lens 140 to provide a flattened surface. For example, the second planarization layer 190 may be disposed in the first opening 130a of the black matrix 130 and cover an upper portion of the lens 140.

For example, the color filter array may include red, green, and blue color filters 150. In this example, each of these color filters may be disposed in a corresponding one of the first openings 130a of the black matrix 130 and cover an upper portion of a corresponding one of the plurality of lens 140. For example, the color filter 150 may be formed to have a concave shape recessed downwardly toward the lens 140 by a patterning process using a photomask or an inkjet printing process.

The shape of the color filter 150 may be determined depending on a difference in height between the black matrix 130 and the color filter 150. For example, when the center of the color filter 150 is positioned lower than or similar to that of the black matrix 130, the color filter 150 may be formed in a concave shape. In another example, when the center of the color filter 150 is positioned higher than that of the black matrix 130, the color filter 150 may be formed in a convex shape.

A portion of the color filter 150 may protrude outside of the black matrix 130. For example, an upper surface of the color filter 150 disposed on the lens 140 may have a concave shape, and thereby, an edge of the upper surface of the color filter 150 may protrude outside of the black matrix 130. In this configuration, respective portions on the black matrix 130 and the color filter 150 may be flattened by a first planarization layer 180 for flattening the curved surface due to such a protrusion. For example, the first planarization layer 180 may be formed to cover respective upper portions of both the black matrix 130 and the color filter 150.

The 3D lens 20 may be disposed on one side of the display panel 10 and can form a stereoscopic image according to binocular parallax. For example, the 3D lens 20 may include a lenticular lens 20a, and a user can perceive a stereoscopic image through the lenticular lens 20a.

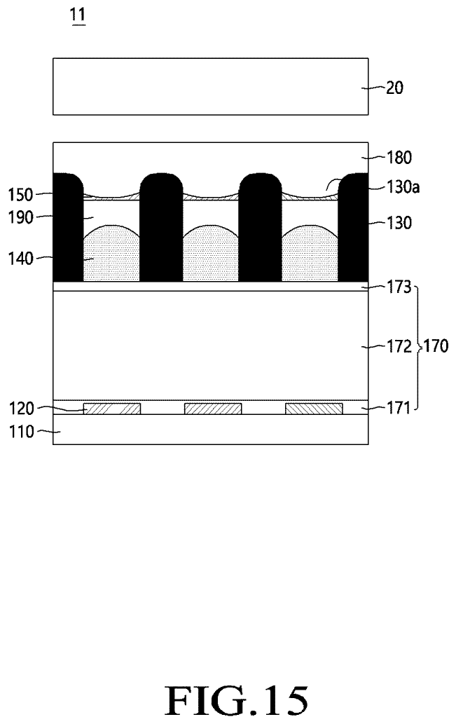

FIG. 15 is a cross-sectional view of a display area DA of a stereoscopic image display device according to another embodiment of the present disclosure. Discussions that follow for the configurations of FIG. 15 are provided by focusing on configurations different from the configurations of FIGS. 1 to 14, for simplicity.

Referring to FIG. 15, a stereoscopic image display device 11 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120.

The stereoscopic image display device 11 may be formed such that the sum of respective heights of the lens 140, a second planarization layer 190 and the color filter 150 is smaller than a height of the black matrix 130 when compared to the stereoscopic image display device 9 of FIG. 14. For example, the lens 140, the second planarization layer 190 and the color filter 150 may be disposed in a first opening 130a of the black matrix 130 and may not protrude outside of the black matrix 130.

According to this configuration, when the lens 140, the second planarization layer 190 and the color filter 150 are disposed inside of the black matrix 130, a thickness of the display panel 10 can be reduced, and thereby, the stereoscopic image display device 11 can be formed lighter and thinner.

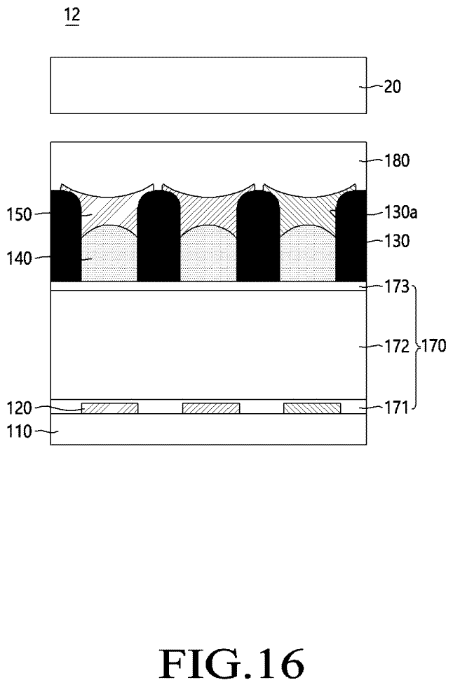

FIG. 16 is a cross-sectional view of a display area DA of a stereoscopic image display device according to another embodiment of the present disclosure. Discussions that follow for the configurations of FIG. 16 are provided by focusing on configurations different from the configurations of FIGS. 1 to 15, for simplicity.

Referring to FIG. 16, a stereoscopic image display device 12 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120. In one or more aspects, the stereoscopic image display device 12 may not include a second planarization layer 190 when compared to the stereoscopic image display device 11 of FIG. 15 described above. In this configuration, since the second planarization layer 190 is omitted from the display panel 10, a thickness of the color filter 150 can be increased, and a thickness of the display panel 10 can be reduced. Thereby, the stereoscopic image display device 12 can be formed lighter and thinner.

The 3D lens 20 may be disposed on one side of the display panel 10 and can form a stereoscopic image according to binocular parallax. For example, the 3D lens 20 may include a lenticular lens 20a, and a user can perceive a stereoscopic image through the lenticular lens 20a.

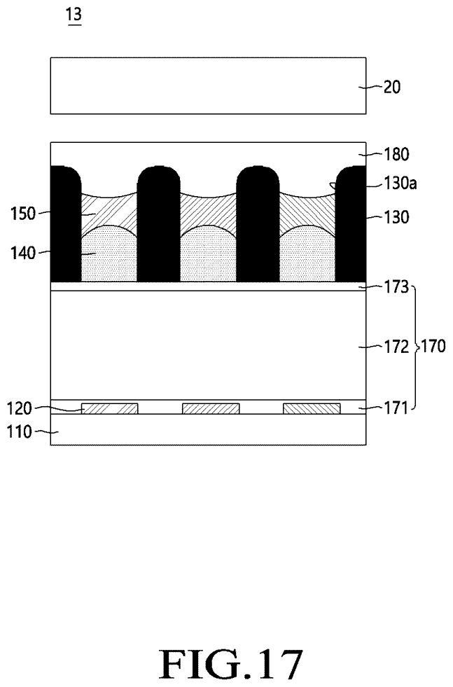

FIG. 17 is a cross-sectional view of a display area DA of a stereoscopic image display device according to another embodiment of the present disclosure. Discussions that follow for the configurations of FIG. 17 are provided by focusing on configurations different from the configurations of FIGS. 1 to 16, for simplicity.

Referring to FIG. 17, a stereoscopic image display device 13 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120.

The stereoscopic image display device 13 may be formed such that on a same horizontal surface, the sum of respective maximum heights of the lens 140 and the color filter 150 is smaller than a height of the black matrix 130 when compared to the stereoscopic image display device 12 of FIG. 16. For example, the lens 140 and the color filter 150 may be disposed in a first opening 130a of the black matrix 130 and may not protrude outside of the black matrix 130.

According to this configuration, when the lens 140 and the color filter 150 are disposed inside of the black matrix 130, a thickness of the display panel 10 can be reduced, and thereby, the stereoscopic image display device 13 can be formed lighter and thinner.

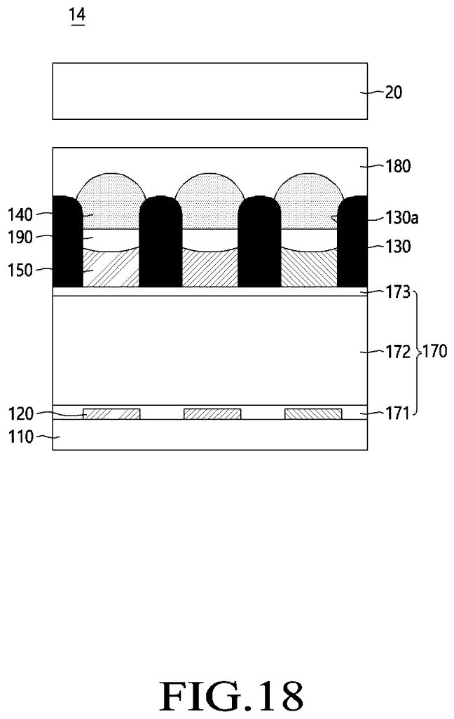

FIG. 18 is a cross-sectional view of a display area DA of a stereoscopic image display device according to another embodiment of the present disclosure. Discussions that follow for the configurations of FIG. 18 are provided by focusing on configurations different from the configurations of FIGS. 1 to 17, for simplicity.

Referring to FIG. 18, a stereoscopic image display device 14 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120.

The base substrate 110 may support various components or layers of the stereoscopic image display device 14 and may include a stack of a plurality of layers.

The light emitting element 120 may be disposed over the base substrate 110, and may include a first electrode 121, which is a pixel electrode (or an anode electrode), a second electrode 122, which is a common electrode (or a cathode electrode), and an emission layer 123 interposed between the first electrode 121 and the second electrode 122.

An encapsulation layer 170 may be disposed on the light emitting element 120 to protect the light emitting element 120 and flatten one or more stacked configurations.

The black matrix 130 may be disposed on the encapsulation layer 170, and a first opening 130a may be formed in an area overlapping with the emission layer 123.

For example, the color filter array may include red, green, and blue color filters 150, and the black matrix 130 may include a plurality of first openings 130a. In this example, each of these color filters may be disposed in a corresponding one of the first openings 130a of the black matrix 130. For example, the color filter 150 may be formed to have a concave shape recessed downwardly toward the encapsulation layer 170 by a patterning process using a photomask or an inkjet printing process.

The color filter 150, a second planarization layer 190, and the lens 140 may be sequentially stacked in the first opening 130a of the black matrix 130. The sum of respective heights of the color filter 150 and the second planarization layer 190 may be formed to be less than a height of the black matrix 130. For example, the color filter 150 and the second planarization layer 190 may be disposed in the first opening 130a of the black matrix 130 and may not protrude outside of the black matrix 130.

According to this configuration, when the color filter 150 and the second planarization layer 190 are located inside of the black matrix 130, a thickness of the display panel 10 can be reduced, and thereby, the stereoscopic image display device 14 can be formed lighter and thinner.

The 3D lens 20 may be disposed on one side of the display panel 10 and can form a stereoscopic image according to binocular parallax. For example, the 3D lens 20 may include a lenticular lens 20a, and a user can perceive a stereoscopic image through the lenticular lens 20a.

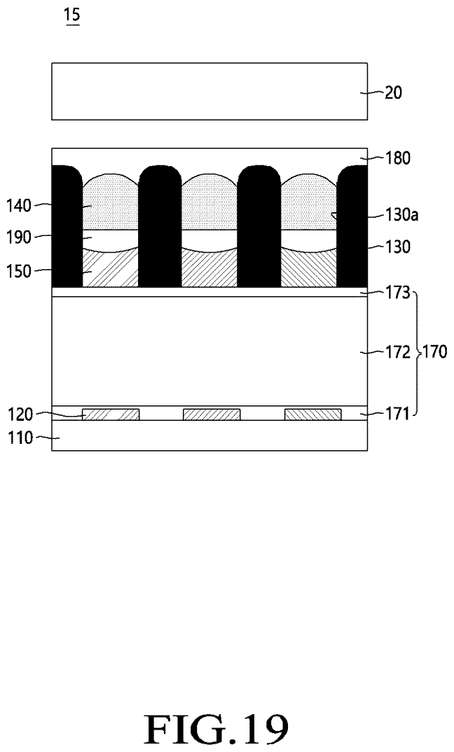

FIG. 19 is a cross-sectional view of a display area DA of a stereoscopic image display device according to another embodiment of the present disclosure. Discussions that follow for the configurations of FIG. 19 are provided by focusing on configurations different from the configurations of FIGS. 1 to 18, for simplicity.

Referring to FIG. 19, a stereoscopic image display device 15 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120.

The stereoscopic image display device 15 may be formed such that on a same horizontal surface, the sum of respective maximum heights of the color filter 150, a second planarization layer 190 and the lens 140 is smaller than a height of the black matrix 130 when compared to the stereoscopic image display device 14 of FIG. 18. For example, the color filter 150, the second planarization layer 190, and the lens 140 may be disposed in a first opening 130a of the black matrix 130 and may not protrude outside of the black matrix 130.

According to this configuration, when the color filter 150, the second planarization layer 190 and the lens 140 are disposed inside of the black matrix 130, a thickness of the display panel 10 can be reduced, and thereby, the stereoscopic image display device 15 can be formed lighter and thinner.

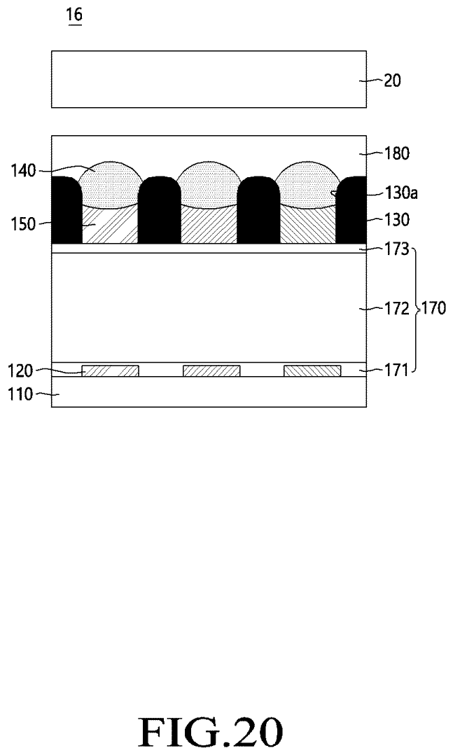

FIG. 20 is a cross-sectional view of a display area DA of a stereoscopic image display device according to another embodiment of the present disclosure. Discussions that follow for the configurations of FIG. 20 are provided by focusing on configurations different from the configurations of FIGS. 1 to 19, for simplicity.

Referring to FIG. 20, a stereoscopic image display device 16 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120. In one or more embodiments, the stereoscopic image display device 16 may not include a second planarization layer 190 when compared to the stereoscopic image display device 15 of FIG. 19 described above. In this configuration, since the second planarization layer 190 is omitted from the display panel 10, a thickness of the display panel 10 can be reduced, and thereby, the stereoscopic image display device 16 can be formed lighter and thinner.

The 3D lens 20 may be disposed on one side of the display panel 10 and can form a stereoscopic image according to binocular parallax. For example, the 3D lens 20 may include a lenticular lens 20a, and a user can perceive a stereoscopic image through the lenticular lens 20a.

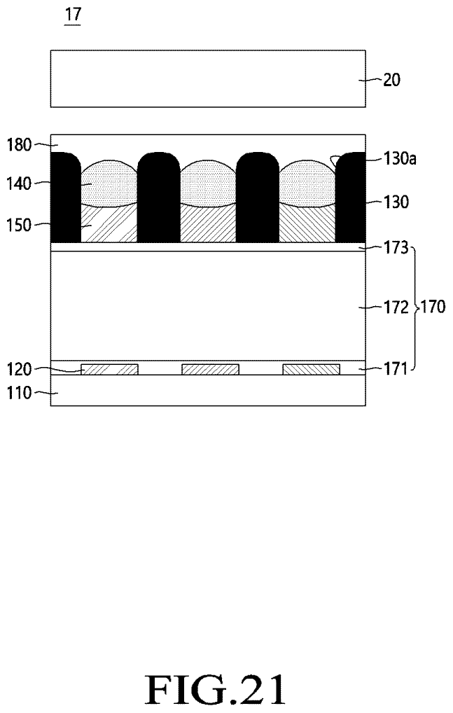

FIG. 21 is a cross-sectional view of a display area DA of a stereoscopic image display device according to another embodiment of the present disclosure. Discussions that follow for the configurations of FIG. 21 are provided by focusing on configurations different from the configurations of FIGS. 1 to 20, for simplicity.

Referring to FIG. 21, a stereoscopic image display device 17 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120.

The stereoscopic image display device 17 may be formed such that on a same horizontal surface, the sum of respective maximum heights of the color filter 150 and the lens 140 is smaller than a height of the black matrix 130 when compared to the stereoscopic image display device 16 of FIG. 20. For example, the color filter 150 and the lens 140 may be disposed in a first opening 130a of the black matrix 130 and may not protrude outside of the black matrix 130.

According to this configuration, when the color filter 150 and the lens 140 are disposed inside of the black matrix 130, a thickness of the display panel 10 can be reduced, and thereby, the stereoscopic image display device 17 can be formed lighter and thinner.

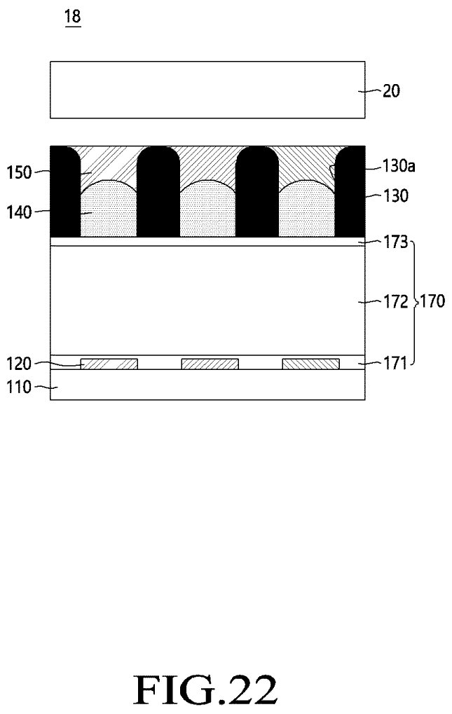

FIG. 22 is a cross-sectional view of a display area DA of a stereoscopic image display device according to another embodiment of the present disclosure. Discussions that follow for the configurations of FIG. 22 are provided by focusing on configurations different from the configurations of FIGS. 1 to 21, for simplicity.

Referring to FIG. 22, a stereoscopic image display device 18 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120.

The base substrate 110 may support various components or layers of the stereoscopic image display device 18 and may include a stack of a plurality of layers.

The light emitting element 120 may be disposed over the base substrate 110, and may include a first electrode 121, which is a pixel electrode (or an anode electrode), a second electrode 122, which is a common electrode (or a cathode electrode), and an emission layer 123 interposed between the first electrode 121 and the second electrode 122.

An encapsulation layer 170 may be disposed on the light emitting element 120 to protect the light emitting element 120 and flatten one or more stacked configurations.

The black matrix 130 may be disposed on the encapsulation layer 170, and a first opening 130a may be formed in an area overlapping with the emission layer 123.

The lens 140 and color filter 150 may be sequentially stacked in the first opening 130a of the black matrix 130.

In one or more embodiments, the lens 140 may be disposed for collecting light emitted from the light emitting element 120, and be a convex lens formed convexly toward the color filter 150.

For example, the color filter array may include red, green, and blue color filters 150, and the black matrix 130 may include a plurality of first openings 130a. In this example, each of these color filters may be disposed in a corresponding one of the first openings 130a of the black matrix 130 and cover an upper portion of a corresponding one of the plurality of lens 140.

In one or more embodiments, an upper surface of the color filter 150 may be flattened by a polishing process, and thereby, the color filter 150 may be formed to have the same height as the black matrix 130 (for example, the upper surface of the color filter 150 is at the same or substantially the same height as the upper surface of the black matrix 130). For example, the color filter 150 may cover an upper portion of the lens 140 in the first opening 130a, and thereby, a portion on the lens 140 may be flattened by the color filter 150.

According to this configuration, as a portion on the convex lens 140 is flattened by the color filter 150, a first planarization layer 180 and a second planarization layer 190 described above can be removed. Therefore, a thickness of the display panel 10 can be reduced, and thereby, the stereoscopic image display device 18 can be formed lighter and thinner.

The 3D lens 20 may be disposed on one side of the display panel 10 and can form a stereoscopic image according to binocular parallax. For example, the 3D lens 20 may include a lenticular lens 20a, and a user can perceive a stereoscopic image through the lenticular lens 20a.

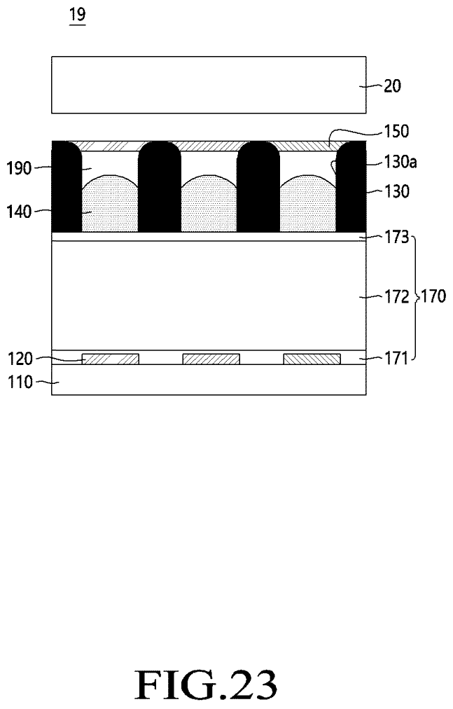

FIG. 23 is a cross-sectional view of a display area DA of a stereoscopic image display device according to another embodiment of the present disclosure. Discussions that follow for the configurations of FIG. 23 are provided by focusing on configurations different from the configurations of FIGS. 1 to 22, for simplicity.

Referring to FIG. 23, a stereoscopic image display device 19 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120.

The stereoscopic image display device 19 may be formed such that a second planarization layer 190 may be disposed between the color filter 150 and the lens 140 when compared to the stereoscopic image display device 18 of FIG. 22. According to this configuration, moisture and undesired substances can be prevented from entering the lens portion 140 through the second planarization layer 190, and the stereoscopic image display device 19 can provide advantages of easily flattening an upper portion of the lens 140 or a portion on the lens 140 because a polishing process for the color filter 150 can be reduced or omitted.

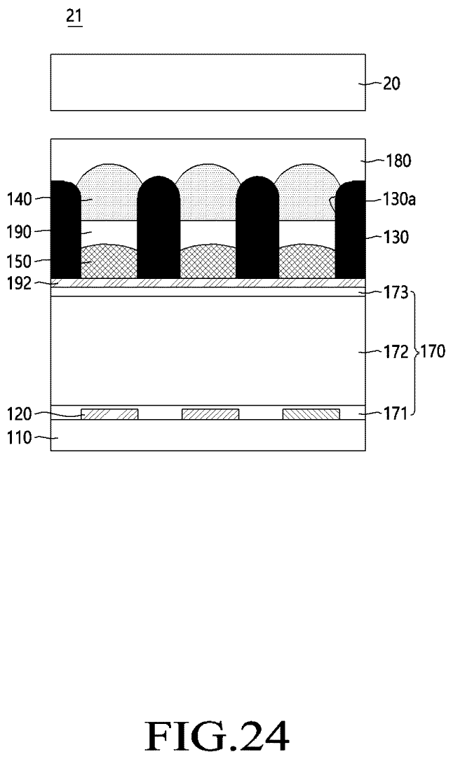

FIG. 24 is a cross-sectional view of a display area DA of a stereoscopic image display device according to another embodiment of the present disclosure. Discussions that follow for the configurations of FIG. 24 are provided by focusing on configurations different from the configurations of FIGS. 1 to 23, for simplicity.

Referring to FIG. 24, a stereoscopic image display device 21 may include a display panel 10 configured to present an image through a display area AA, and a 3D lens 20 disposed on one surface of the display panel 10.

The display panel 10 may include a base substrate 110, at least one light emitting element 120, a black matrix 130, a lens array including at least one lens 140, and a color filter array including at least one color filter 150. Hereinafter, for convenience of description, discussions are provided by focusing on one lens 140 included in the lens array, one color filter 150 included in the color filter array, and one light emitting element 120 among the at least one light emitting element 120.

The stereoscopic image display device 21 may be formed such that the color filter 150 may be formed in a convex shape and be formed as a one-type color filter allowing all of red wavelengths, green wavelengths, and blue wavelengths to be transmitted when compared to the stereoscopic image display device 14 of FIG. 18. According to this configuration, since the color filter 150 is formed to transmit all of the red, green, and blue wavelengths, the stereoscopic image display device 21 can provide advantages of reducing the number of masks required to deposit color filters 150, and thereby, reducing the manufacturing time and manufacturing cost.

In one or more embodiments, the stereoscopic image display device 21 may further include an optical layer 192 between the base substrate 110 and the color filter 150.

The optical layer 192 may be disposed on the encapsulation layer 170. The optical layer 192 may selectively transmit some light having wavelengths greater than or equal to a reference wavelength and selectively reflect some light having wavelengths lower than the reference wavelength, among light output from the light emitting element 120. This is because, when the color filter 150 is formed as a one-type color filter through which all of the red, green, and blue wavelengths can be transmitted, in the stereoscopic image display device 21, transmission efficiency may be lowered when compared to the stereoscopic image display device 14 of FIG. 18 including the red, green, and blue color filters 150.

The optical layer 192 may be formed by adding an absorbing dye and pigment for controlling the transmission of the red, green, and blue wavelength bands to a polymer material of the photo acryl, epoxy, and PI series. In one or more aspects, the optical layer 192 may further include a dye and pigment for blocking unnecessary wavelengths.

Therefore, the stereoscopic image display device 21 including a structure where the optical layer 192 is used to selectively transmit and reflect light emitted from the light emitting element 120 can provide advantages of improving the transmission efficiency of the blue light, the red light, and the green light. For example, when the color filter 150 transmits more blue light than the red, green, and blue color filters discussed above, the color filter 150 can selectively reflect light of wavelengths less than 500 nm, and selectively transmit light of wavelengths greater than or equal to 500 nm. In one or more aspects, the optical layer 192 can be applied not only to a structure to which a one-type color filter 150 is employed, but also to a structure to which red, green, and blue color filters are applied.

The examples, aspects, and embodiments described above will be briefly described as follows.

According to the one or more example embodiments described herein, a stereoscopic image display device can be provided that includes a display panel including a display area and a non-display area surrounding the display area, and displaying an image through the display area, a 3D lens disposed on one side of the display panel, the display panel including a base substrate, at least one light emitting element disposed on the base substrate, a black matrix disposed over the at least one light emitting element and having at least one first opening, at least one lens disposed in the at least one first opening, and at least one color filter disposed to face the at least one lens. In one or more embodiments, in the at least one first opening, respective side portions of the at least one lens and the at least one color filter may correspond to the black matrix.

In one or more embodiments, the display panel may further include a bank layer comprising a second opening in an area corresponding to the at least one first opening, an encapsulation layer covering the at least one light emitting element, and a first planarization layer disposed under the 3D lens and covering the at least one lens or the at least one color filter.

In one or more embodiments, the at least one lens may be a convex lens formed convexly or a concave lens formed concavely, in a direction facing the color filter.

In one or more embodiments, the at least one lens may be formed by an inkjet printing process.

In one or more embodiments, an upper surface of the at least one color filter is convex upwardly or concave downwardly.

In one or more embodiments, the at least one color filter may be formed by a patterning process using a photomask or an inkjet printing process.

In one or more embodiments, the at least one color filter may be disposed in the at least one first opening, and on a same horizontal surface, the sum of respective maximum heights of the at least one lens and the at least one color filter may be less than a height of the black matrix.

In one or more embodiments, a portion of the at least one lens or the at least one color filter may protrude outside of the black matrix.

In one or more embodiments, the at least one color filter may cover an upper portion of the at least one lens in the at least one first opening.

In one or more embodiments, an upper surface of the at least one color filter may be flattened by a polishing process, so that the at least one color filter may have the same height as the black matrix.

In one or more embodiments, the stereoscopic image display device may further include a second planarization layer disposed between the at least one lens and the at least one color filter.

In one or more embodiments, the second planarization layer may cover an upper portion of the at least one lens, and the at least one color filter may be disposed on the second planarization layer.

In one or more embodiments, a height of the at least one lens may be less than a height of the black matrix, and a height of the at least one color filter may be less than the height of the black matrix.

In one or more embodiments, the second planarization layer may be disposed in the at least one first opening of the black matrix.

In one or more embodiments, on a same horizontal surface, the sum of respective maximum heights of the at least one lens and the second planarization layer may be less than a height of the black matrix.

In one or more embodiments, on a same horizontal surface, the sum of respective maximum heights of the at least one color filter and the second planarization layer may be less than a height of the black matrix.

In one or more embodiments, the at least one color filter may be a one-type color filter through which red, green, and blue wavelengths can be transmitted.

In one or more embodiments, the stereoscopic image display device may further include an optical layer disposed between the base substrate and the at least one color filter, and can selectively transmit light having wavelengths higher than or equal to a reference wavelength and selectively reflect light having wavelengths lower than the reference wavelength, among light output from the at least one light emitting element.

In one or more embodiments, a curvature of the at least one lens may increase in proportional to a surface energy difference with an element or layer contacting a curve side of the at least one lens, and a curvature of the at least one color filter may increase in proportional to a surface energy difference with an element or layer contacting a curve side of the at least one color filter.

In one or more embodiments, the at least one color filter may be disposed on the at least one lens and have a downward concave upper surface, and an edge of the downward concave upper surface may protrude outside of the black matrix.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present invention. The above description and the accompanying drawings provide an example of the technical idea of the present invention for illustrative purposes only. That is, the disclosed embodiments are intended to illustrate the scope of the technical idea of the present invention.

What is claimed is:

1. A stereoscopic image display device comprising:
a display panel comprising a display area and a non-display area surrounding the display area, the display panel displaying an image through the display area; and
a three-dimensional (3D) lens on one side of the display panel,
wherein the display panel comprises:
a base substrate;
at least one light emitting element on the base substrate;
a black matrix over the at least one light emitting element, the black matrix having at least one first opening;
at least one lens in the at least one first opening; and
at least one color filter that faces the at least one lens,
wherein in the at least one first opening, respective side portions of the at least one lens and the at least one color filter correspond to the black matrix.

2. The stereoscopic image display device of claim 1, wherein the display panel further comprises:
a bank layer comprising a second opening in an area corresponding to the at least one first opening;
an encapsulation layer covering the at least one light emitting element; and
a first planarization layer under the 3D lens, the first planarization layer covering the at least one lens or the at least one color filter.

3. The stereoscopic image display device of claim 1, wherein the at least one lens is a convex lens formed convexly or a concave lens formed concavely in a direction facing the at least one color filter.

4. The stereoscopic image display device of claim 1, wherein the at least one lens is formed by an inkjet printing process.

5. The stereoscopic image display device of claim 1, wherein an upper surface of the at least one color filter is convex upwardly or concave downwardly.

6. The stereoscopic image display device of claim 1, wherein the at least one color filter is formed by a patterning process using a photomask or an inkjet printing process.

7. The stereoscopic image display device of claim 1, wherein the at least one color filter is disposed in the at least one first opening, and on a same horizontal surface, a sum of respective maximum heights of the at least one lens and the at least one color filter is less than a height of the black matrix.

8. The stereoscopic image display device of claim 1, wherein a portion of the at least one lens or the at least one color filter protrudes outside of the black matrix.

9. The stereoscopic image display device of claim 1, wherein the at least one color filter covers an upper portion of the at least one lens in the at least one first opening.

10. The stereoscopic image display device of claim 9, wherein an upper surface of the at least one color filter is flattened by a polishing process, so that the at least one color filter is a same height as the black matrix.

11. The stereoscopic image display device of claim 1, further comprising:
a second planarization layer between the at least one lens and the at least one color filter.

12. The stereoscopic image display device of claim 11, wherein the second planarization layer covers an upper portion of the at least one lens and the at least one color filter is on the second planarization layer.

13. The stereoscopic image display device of claim 12, wherein a height of the at least one lens is less than a height of the black matrix and a height of the at least one color filter is less than the height of the black matrix.

14. The stereoscopic image display device of claim 11, wherein the second planarization layer is in the at least one first opening of the black matrix.

15. The stereoscopic image display device of claim 14, wherein on a same horizontal surface, a sum of respective maximum heights of the at least one lens and the second planarization layer is less than a height of the black matrix.

16. The stereoscopic image display device of claim 14, wherein on a same horizontal surface, a sum of respective maximum heights of the at least one color filter and the second planarization layer is less than a height of the black matrix.

17. The stereoscopic image display device of claim 1, wherein the at least one color filter is a one-type color filter through which red wavelength light, green wavelength light, and blue wavelength light are transmitted.

18. The stereoscopic image display device of claim 17, further comprising:
an optical layer between the base substrate and the at least one color filter, the optical layer selectively transmitting light having wavelengths greater than or equal to a reference wavelength and selectively reflecting light having wavelengths less than the reference wavelength, among light output from the at least one light emitting element.

19. The stereoscopic image display device of claim 1, wherein a curvature of the at least one lens increases in proportional to a surface energy difference with an element or layer contacting a curve side of the at least one lens and a curvature of the at least one color filter increases in proportional to a surface energy difference with an element or layer contacting a curve side of the at least one color filter.

20. The stereoscopic image display device of claim 1, wherein the at least one color filter is on the at least one lens and has a downward concave upper surface and an edge of the downward concave upper surface protrudes outside of the black matrix.
